(19) United States
(12) Patent Application Publication
(10) Pub. No.: US 2007/0194308 A1
(43) Pub. Date: Aug. 23, 2007

(54) Organic light emitting display capable of showing images on double sides thereof

(75) Inventor: Chien-Chung Kuo, Taichung County (TW)

Correspondence Address: BACON & THOMAS, PLLC, 625 SLATERS LANE, FOURTH FLOOR, ALEXANDRIA, VA, 22314, US

(73) Assignee: WINTEK CORPORATION, TAICHUNG (TW)

(21) Appl. No.: 11/790,315

(22) Filed: Apr. 25, 2007

Related U.S. Application Data
(63) Continuation-in-part of application No. 11/166,088, filed on Jun. 27, 2005, now abandoned.

(51) Int. Cl. H01L 29/08; H01L 35/24; H01L 51/00

(52) U.S. Cl. 257/40

(57) ABSTRACT

An organic light emitting display (OLED) has a substrate, on two opposite sides of which a fist electrode, an organic layer and a second electrode are stacked in sequence respectively. To prevent the light of the organic layers at the opposite sides of the substrate from interference, the substrate or the first electrode can be made of opaque materials, or at least an opaque light barrier layer is provided between the substrate and the first electrode or between the first electrode and the organic layer.

### CROSS REFERENCE TO RELATED APPLICATION

This application is a Continuation-In-Part of U.S. patent application Ser. No. 11/166,088 filed on Jun. 27, 2005.

### BACKGROUND OF THE INVENTION

1. Field of the Invention

The present invention relates generally to a display, and more particularly to an organic light emitting display capable of showing images on double sides thereof

2. Description of the Related Art

Organic light emitting displays (OLED) have many advantages such as self-lighting, wide viewing angle, high luminance, and high efficiency so that OLED is widely incorporated in the consumer electron products such as mobile phone, digital camera and game platform. The earlier OLEDs only show images at a single, in the present time, manufacturers are working on how to show images on opposite sides.

FIG. 10 shows a conventional organic light emitting display 85, which has an organic light emitting unit 86 with a transparent anode 87 and a transparent cathode 88 on two opposite sides thereof. After a voltage provided to the anode 87 and the cathode 88, two interlaced display regions 89 emit light respectively. FIG. 11 shows another conventional organic light emitting display 90, which has a substrate 92 with two organic light emitting units 91 on two opposite sides thereof. The organic light emitting units 91 emit light to two opposite directions. FIG. 12 shows the third conventional organic light emitting display 93, which has two organic light emitting units 94 attached back to back such that the organic light emitting display 93 shows images on double sides. These conventional organic light emitting displays have a greater size that cannot be installed in a smaller electronic product. FIG. 13 shows the fourth conventional organic light emitting display 95, which has two integrally encapsulated organic light emitting display units 96. Each organic light emitting display unit 96 has a metal electrode 97 coated with an opaque insulation layer 98. The organic light emitting display units 96 have the opaque insulation layer 98 attached on each other for encapsulation, such that the organic light emitting display units 96 show independent images. FIG. 14 shows the fifth conventional organic light emitting display 100, which an organic light emitting display unit 101 emits light through a transparent indium tin oxide (ITO) film 102 and a substrate 103 and through an organic transport layer 104, an electron injection layer 105, a thin metal film 106 and a transparent conductive film 107 respectively to show images on double sides.

In conclusion, all of the conventional organic light emitting displays described above have the drawbacks of large in size, heavier in weight or cannot show independent images on double side. They have many restrictions and problems to be applied in the electronic products.

### SUMMARY OF THE INVENTION

The primary objective of the present invention is to provide an organic light emitting display, which is capable of showing images at double sides independently and is smaller in size and lighter in weight to be incorporated in various products.

According to the objective of the present invention, an organic light emitting display comprises a substrate, on opposite sides of which a fist electrode, an organic layer and a second electrode are stacked in sequence respectively. To prevent the light of the organic layers at the opposite sides of the substrate from interference, the substrate or the first electrode can be made of opaque materials, or at least an opaque light barrier layer is provided between the substrate and the first electrode or between the first electrode and the organic layer.

### BRIEF DESCRIPTION OF THE DRAWINGS

FIG. 1 is a sectional view of a first preferred embodiment of the present invention;

FIG. 2 is a sectional view, showing the OLED of the first preferred embodiment of the present invention installed in the mobile phone;

FIG. 3 is a sectional view, showing the liquid crystal display and the OLED of the first preferred embodiment of the present invention installed in the mobile phone;

FIG. 4 is a sectional view of a second preferred embodiment of the present invention, showing the light barrier layer between the first electrode on the top of the substrate and the substrate;

FIG. 5 is a sectional view of a third preferred embodiment of the present invention, showing the light barrier layer between the first electrode on the bottom of the substrate and the substrate;

FIG. 6 is a sectional view of a fourth preferred embodiment of the present invention, showing the light barrier layers between the substrate and the first electrodes respectively;

FIG. 7 is a sectional view of a fifth preferred embodiment of the present invention, showing light barrier layer between the first electrode on the top of the substrate and the organic layer;

FIG. 8 is a sectional view of a sixth preferred embodiment of the present invention, showing light barrier layer between the first electrode on the bottom of the substrate and the organic layer;

FIG. 9 is a sectional view of a seventh preferred embodiment of the present invention, showing the light barrier layers between the organic layers and the first electrodes respectively;

FIG. 10 is a sectional view of an eighth preferred embodiment of the present invention, showing that the substrate is transparent and the first electrodes are transparent.

FIG. 11 shows a sketch diagram of the first conventional OLED;

FIG. 12 shows a sketch diagram of the second conventional OLED;

FIG. 13 shows a sketch diagram of the third conventional OLED;

FIG. 14 shows a sketch diagram of the fourth conventional OLED, and

FIG. 15 shows a sketch diagram of the fifth conventional OLED.

### DETAILED DESCRIPTION OF THE INVENTION

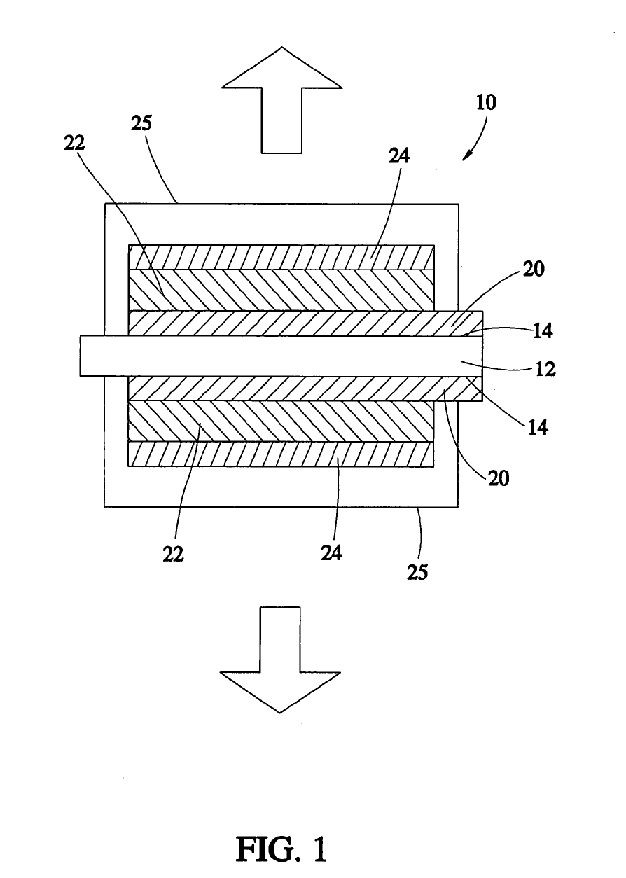

As shown in FIG. 1, an organic light emitting display (OLED) 10 of the first preferred embodiment of the present invention comprises a substrate 12, two first electrodes 20, two organic layers 22 and two second electrodes 24.

The substrate 12 is made of an opaque material having two sides 14 on a top and a bottom thereof.

Each first electrode 20 is an indium tin oxide (ITO) film, which is a conductive and transparent material. The first electrodes 20 are attached on the top and bottom sides 14 of the substrate 12 respectively to form an anode.

The organic layers 22, which may include hole injection layer, hole transport layer, emitting layer or electron transport layer etc., are attached on the first electrodes 20 respectively opposite to the substrate 12.

The second electrodes 24, which are transparent conductive films, are attached on the organic layers 22 respectively opposite to the first electrodes 20. The second electrodes 24 are a cathode pad. A encapsulation member 25 is provided on the sides 14 of the substrate 12 to embed the first electrodes 20, the organic layers 22 and the second electrodes 24. While the encapsulation member 25 uses passivation, a thickness of the display is reduced.

While holes and electrons enter the first electrodes 20 and the second electrodes 24 on the sides 14 of the substrate 12 respectively and go to the organic layers 22 between the first and second electrodes 20, 24, the holes are combined with the electrons to emit light, and the light projects out of the display through the second electrodes 24 respectively.

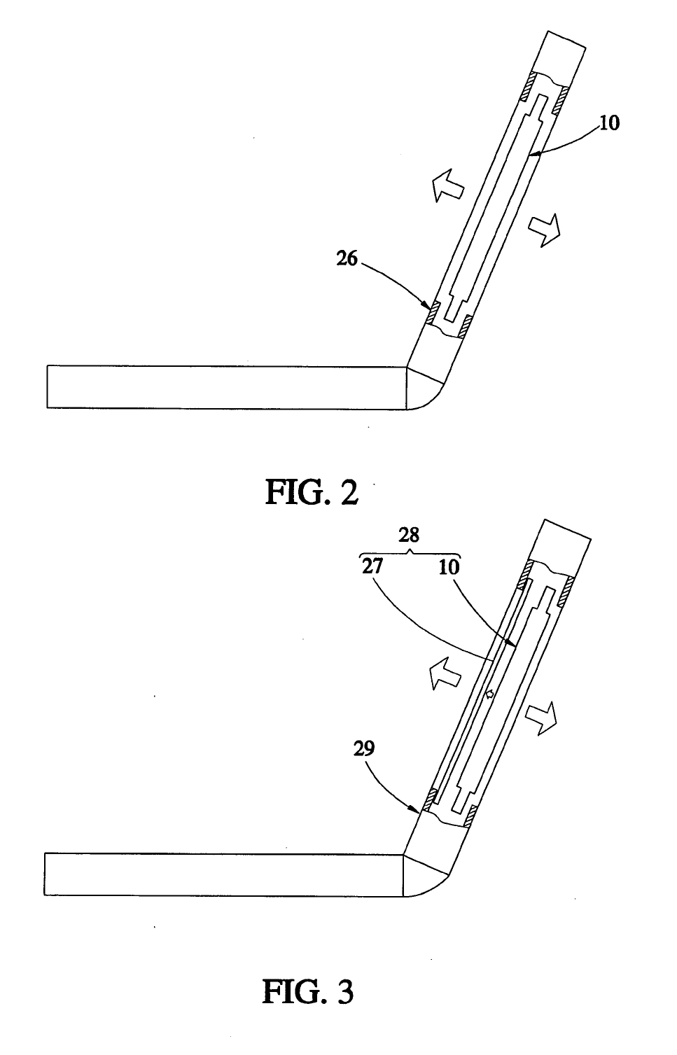

The first and second electrodes 20, 24 and the organic layers 22 are stacked on the sides 14 of the substrate 12 that the thickness of the display is thinner than that of the conventional displays and the size thereof is reduced too. The organic layers 22 are driven by the neighboring first and second electrodes 20, 24 independently for emitting light without any interference. As shown in FIG. 2, the OLED 10 of the first embodiment of the present invention is installed in a cover of a folded mobile phone 26. The mobile phone 26 may have a smaller size and a thinner thickness to get a greater flexibility in design.

As shown in FIG. 3, the OLED 10 of the present invention and a liquid crystal display module 27 are combined to be a display apparatus 28 capable of showing images on double sides, and the display apparatus 28 is installed in a mobile phone 29. The light from a side of the OLED 10 of the present invention and projected to the liquid crystal display module 27 is a backlight of the liquid crystal display module 27. The liquid crystal display module 27 is taken as a main-display of the mobile phone 29 and the OLED 10 projecting light to the side opposite to the liquid crystal display module 27 is a sub-display of the mobile phone 29.

As a result, the organic light emitting display of the present invention is smaller in size, lighter in weight and capable of showing images independently on double sides to be installed in various products.

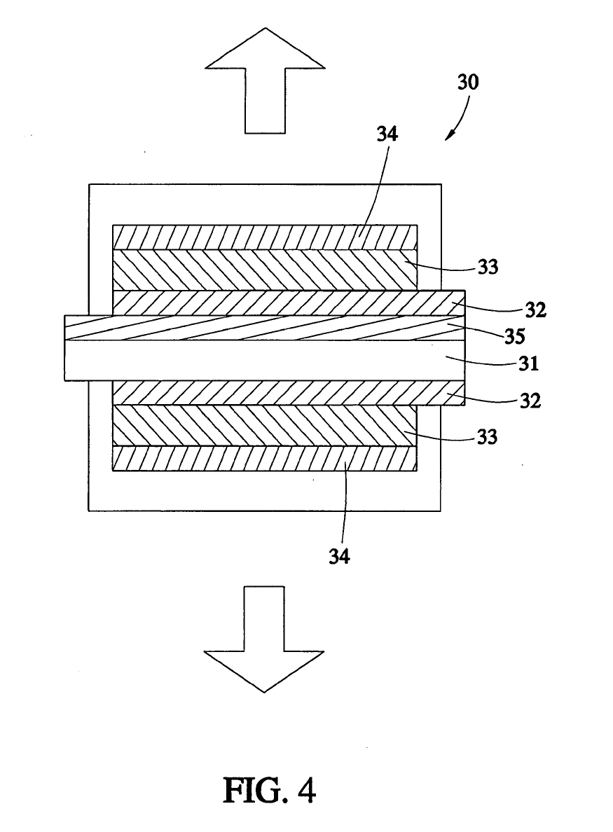

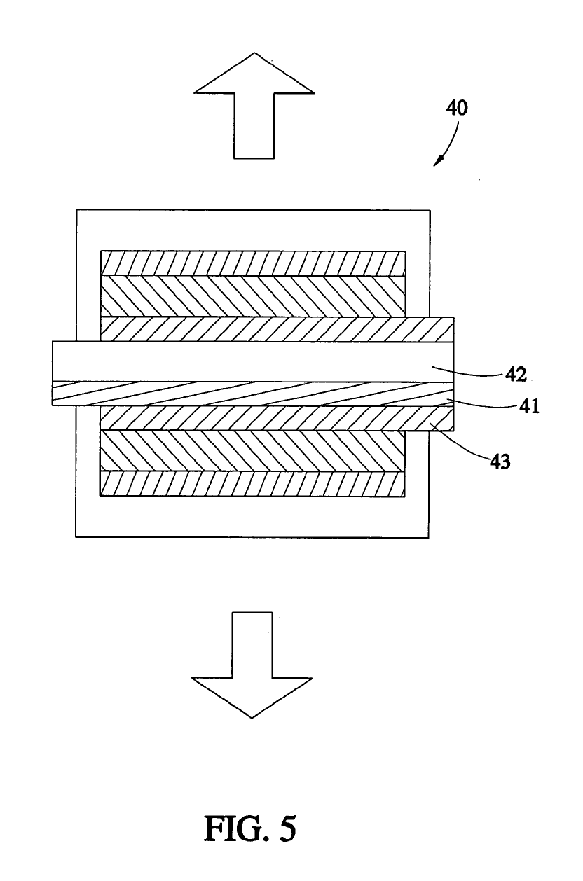

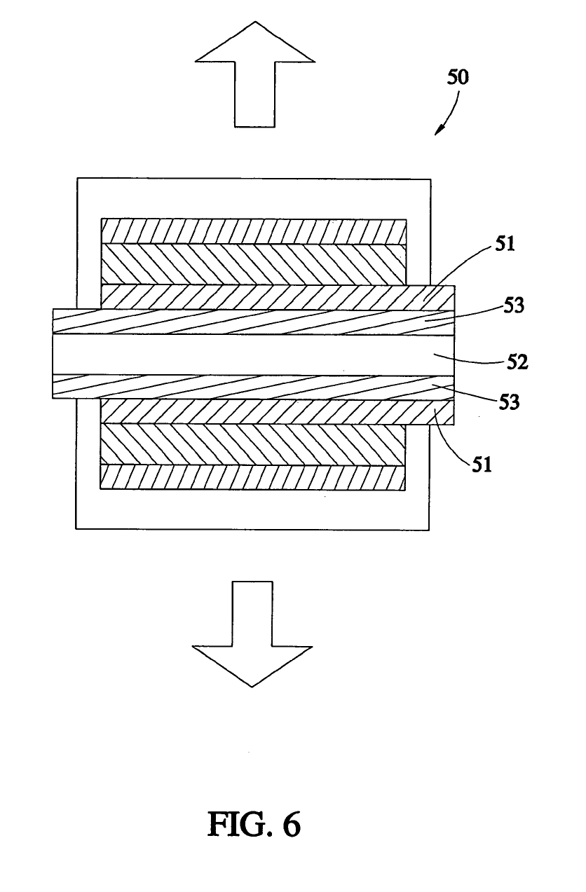

It has to be mentioned that the substrate may be made of a transparent material, and the at least the first electrode is opaque such that it prevents the light from the organic layers from interference. It may be provides with a light barrier layer on the substrate to prevent the light projected from the organic layers from interference. FIG. 4 shows an organic light emitting display 30 of the second preferred embodiment of the present invention, similar to the first preferred embodiment, comprising a substrate 31, two first electrodes 32, two organic layer 33, two second electrodes 34 and a light barrier layer 35. The light barrier layer 35 is between the substrate 31 and the first electrode 32 on a top side of the substrate 31. The light barrier layer 35 and the first electrode 32 prevent the light of the organic layer 33 on the top side of the substrate 31 from projecting to a bottom side of the substrate 31. FIG. 5 shows an organic light emitting display 40 of the second preferred embodiment of the present invention, which is similar to the second preferred embodiment, except that a light barrier layer 41 is between a substrate 42 and a first electrode 43 on a bottom side of the substrate 42. FIG. 6 shows an organic light emitting display 50 of the fourth preferred embodiment of the present invention, wherein the character in that two light barrier layer 53 are provided between opposite sides of a substrate 52 and two first electrodes 51 respectively.

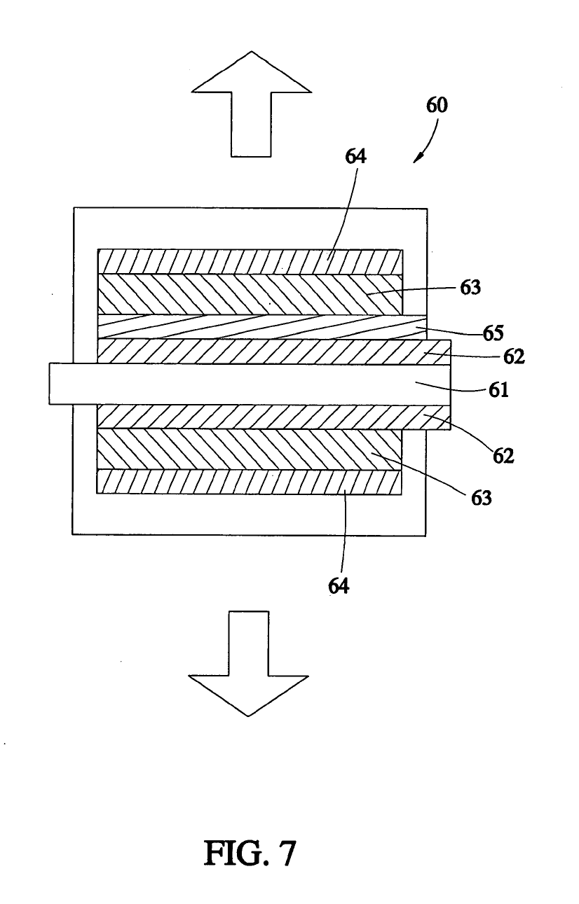

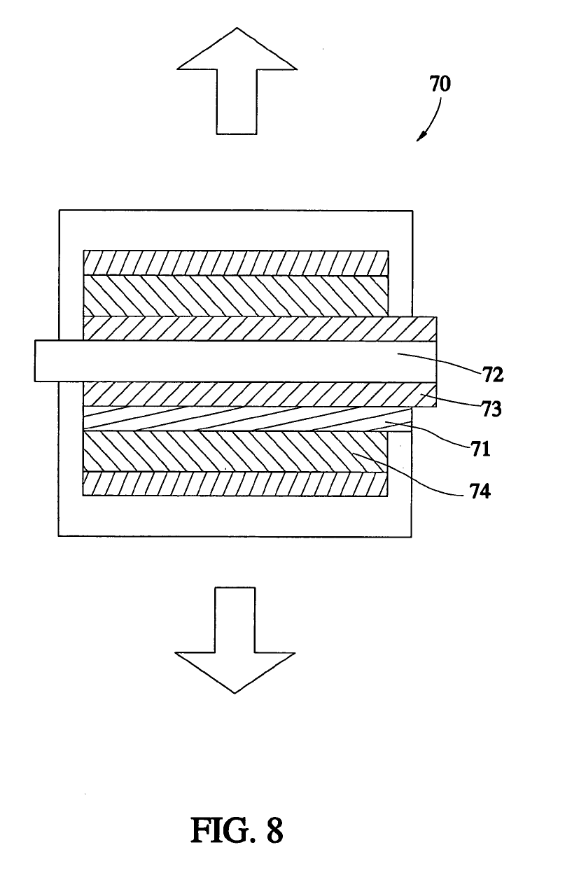

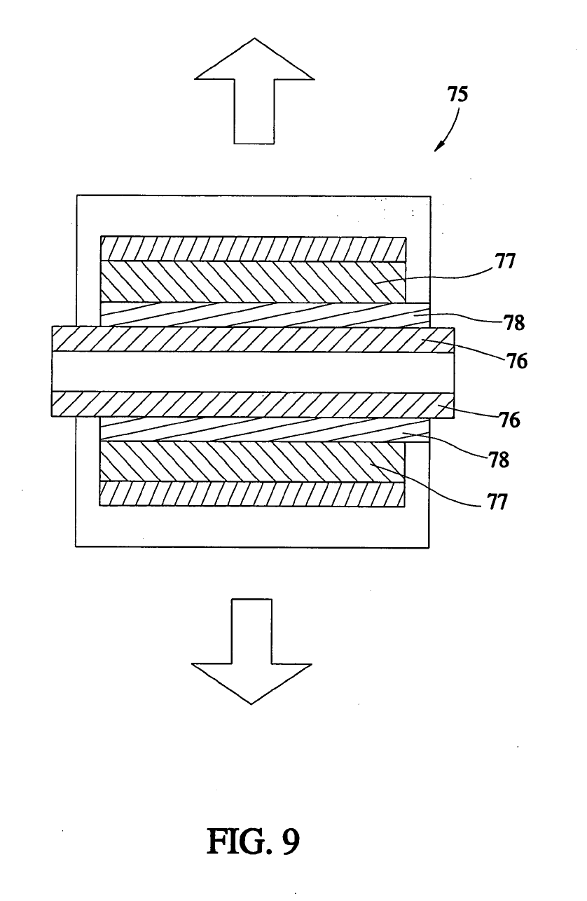

As shown in FIG. 7, an organic light emitting display 60 of the fifth preferred embodiment of the present invention, which is similar to the second embodiments, comprises a substrate 61, two first electrodes 62, two organic layers 63, two second electrodes 64 and a light barrier layer 65. The character is that the light barrier 65 is between the first electrode 62 and the organic layer 63 on a top side of the substrate 61. FIG. 8 shows an organic light emitting display 70 of the sixth preferred embodiment of the present invention, wherein a light barrier 71 is between a first electrode 73 on a bottom side of a substrate 72 and an organic layer 74. FIG. 9 shows an organic light emitting display 75 of the fourth preferred embodiment of the present invention, wherein the character in that two light barrier layer 78 are provided between opposite sides of a substrate 77 and two first electrodes 76 respectively.

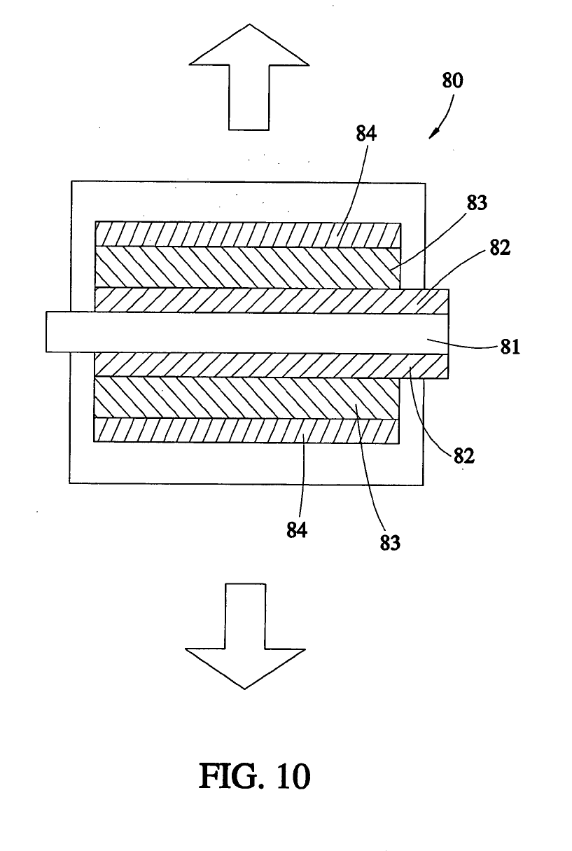

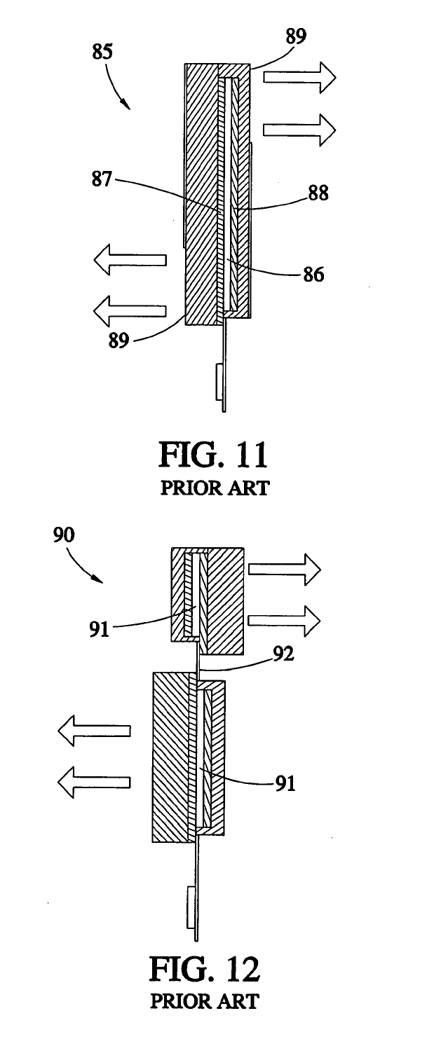

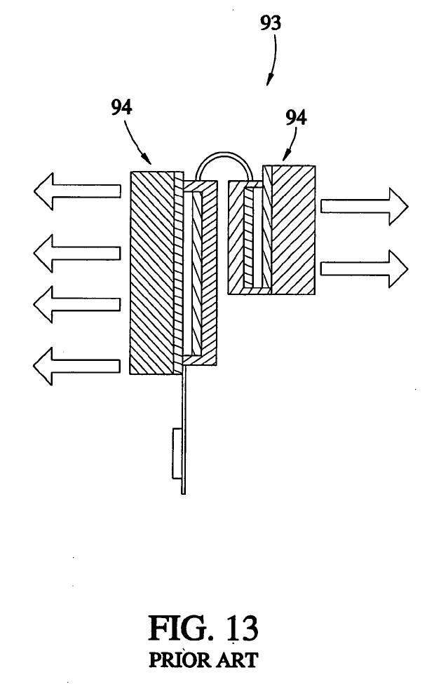

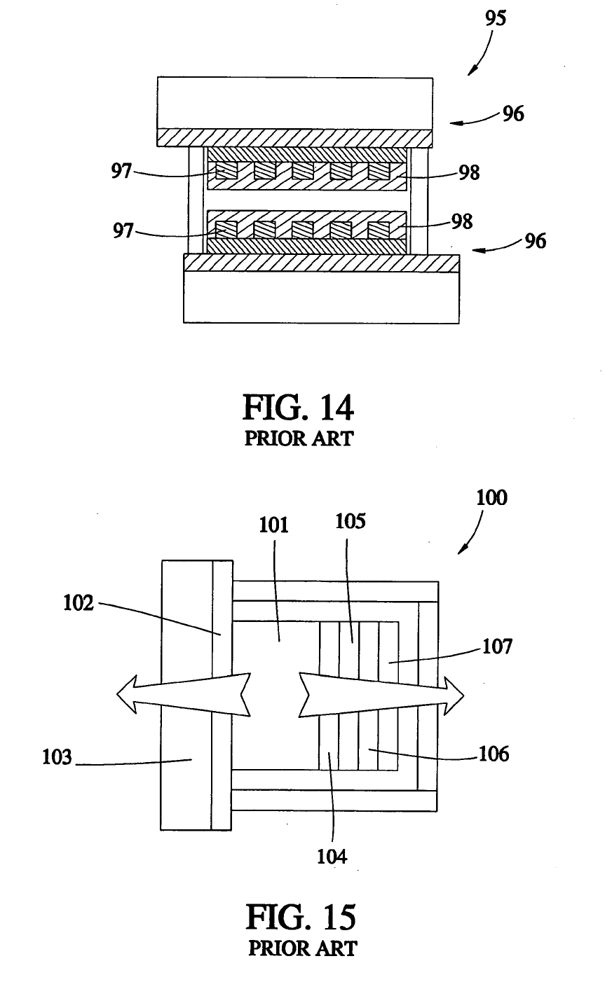

FIG. 10 illustrates an organic light emitting display 80 of the eighth preferred embodiment of the present invention. The organic light emitting display 80 is structurally similar to that of the first preferred embodiment but different as recited as follows. The substrate 81 of the organic light emitting display 80 is made of a transparent plate and the two first electrodes 82 are still made of transparent material. Because the organic layers 83 can be individually connected with the respective first and second electrodes 82 and 84 for illumination driven thereby. In light of this, when the organic layer 83 at one side is controlled not to be driven for illumination and the other organic layer 83 at the other side is controlled to be driven for illumination, the organic light emitting display 80 is provided with display effect resulted from one single side. The aforesaid driving means is frequently applied to the display device having a primary screen and a secondary screen for switchover of the two screens.

The organic light emitting displays of above embodiments can be changed to reverse type OLED, and the driving modes of the OLED can be AMOLED or PMOLED. The substrate can be made of a flexible material, and both of the substrate and the first electrodes can be made of opaque materials. All of that can achieve the objective of the present invention. Furthermore, the OLED of each of the above-mentioned preferred embodiments can alternatively be combined with the liquid crystal display module to form a double-sides display device.

What is claimed is:

1. An organic light emitting display (OLED), comprising:
a substrate;
two first electrodes mounted to two opposite sides of the substrate respectively;
two organic layers each mounted to an opposite side of the first electrode to the substrate, and
two second electrodes each mounted to an opposite side of the organic layer to the first electrode.

2. The OLED as defined in claim 1, the substrate is a plate made of opaque material.

3. The OLED as defined in claim 2, further comprising an encapsulation member embedding the substrate, the first electrodes, the organic layers, and the second electrodes therein, wherein each of the first electrodes has an end exposed outside the encapsulation member.

4. The OLED as defined in claim 1, wherein the substrate is a transparent plate, the OLED further comprising at least one light barrier layer, the at least one light barrier layer being located between the substrate and one of the first electrodes.

5. The OLED as defined in claim 4, further comprising an encapsulation member embedding the substrate, the at least one light barrier layer, the first electrodes, the organic layers, and the second electrodes therein, wherein each of the first electrodes has an end exposed outside the encapsulation member,

6. The OLED as defined in claim 1, wherein the substrate is a transparent plate, the OLED further comprising at least one light barrier layer, the at least one light barrier layer being located between the first electrode and the organic layer, both of which are located at the same side of the substrate.

7. The OLED as defined in claim 6, further comprising an encapsulation member embedding the substrate, the at least one light barrier layer, the first electrodes, the organic layers, and the second electrodes therein, wherein each of the first electrodes has an end exposed outside the encapsulation member.

8. The OLED as defined in claim 1, wherein the substrate is a transparent plate.

9. The OLED as defined in claim 8, wherein one of the two first electrodes is opaque and the OLED further comprises an encapsulation member embedding the substrate, the first electrodes, the organic layers, and the second electrodes therein, wherein the first electrodes have an end exposed outside the encapsulation member.

10. The OLED as defined in claim 8, wherein the two first electrodes are transparent and the OLED further comprises an encapsulation member embedding the substrate, the first electrodes, the organic layers, and the second electrodes therein, wherein the first electrodes have an end exposed outside the encapsulation member.

11. The OLED as defined in claim 1, wherein the substrate and the first electrodes are transparent.
